(19) United States
(12) Patent Application Publication
(10) Pub. No.: US 2022/0090760 A1
(43) Pub. Date: Mar. 24, 2022

(54) LED WHITE LIGHT SOURCE WITH A BIOLOGICALLY ADEQUATE EMISSION SPECTRUM

(71) Applicant: RESEARCH AND DEVELOPMENT CENTER “BIOLUMEN” LIMITED LIABILITY COMPANY, Fryazino (RU)

(72) Inventor: Vladimir Nikolaevich ULASYUK, Fryazino (RU)

(21) Appl. No.: 17/423,920

(22) PCT Filed: Jan. 18, 2019
(86) PCT No.: PCT/RU2019/000028

§ 371 Date: Jul. 19, 2021

(51) Int. Cl. F21V 9/32; H01L 33/44; H01L 33/50

(52) U.S. Cl. CPC F21V 9/32; H01L 33/502; H01L 33/44

(57) ABSTRACT

The invention relates to electrical and electronic engineering, more specifically to light sources based on semiconductor light emitting diodes (LEDs), and more particularly to white light sources based on LEDs with conversion photoluminophores. A biologically adequate emission white LED light source includes at least two white LEDs located on a heat-conducting printed circuit board with electrical leads for connecting the LEDs to a power source, and a translucent cover located above the printed circuit board, each white LED containing a light-reflecting case at least one chip with cyan radiation, embedded in a polymer composition with its own photophosphor or a mixture of photophosphors, while at least one LED with cyan radiation, coated with a composite photoluminescent film containing a transparent phosphor phosphor, is additionally placed on the heat-conducting printed circuit board. The technical result consists in reducing the harmful effects of radiation on the human body, increasing the reliability and efficiency of the light source.

### FIELD OF THE INVENTION

The invention relates to electrical and electronic engineering, more specifically to light sources based on semiconductor light emitting diodes (LEDs), and more particularly to white light sources based on LEDs with conversion photoluminophores.

### STATE OF THE ART

Solid state lighting technology is conquering the lighting market thanks to advances in the development of efficient LEDs, especially nitride (InGaN), and the highest achievable lighting efficiency among all known white light sources. LED solutions are widely used in those lighting devices, such as linear and street luminaires, in which the illuminator is relatively large and highly heated LEDs can be distributed so as to facilitate efficient heat removal from them. The development of LED substitutes for traditional incandescent lamps and halogen lamps with a small form factor with a high luminous flux, in view of the significant prospects for solving the problem of energy conservation, is one of the most urgent modern scientific and technical problems, but its solution is greatly complicated by the volume limitations for the placement of control electronics (drivers) and a relatively small surface to remove the heat generated by the LEDs in such lamps. White LEDs often include blue LEDs coated with YAG:Ce. High-power (one watt or more) blue LEDs have an efficiency of approximately 30-45%, with approximately 550-700 mW allocated to heat the device from each applied watt. In addition, it is believed that when photoluminophore converts blue light into yellow light in white LEDs, approximately 20% of the incident light energy is spent on phosphorus heating. Technical specifications indicate that the power drop of blue LEDs is approximately 7% at a temperature of 25-125° C., while the power drop of white LEDs is approximately 20% at the same temperature. Thus, in high-power white LEDs there are significant restrictions on heat and light fluxes.

The basis of any LED lamp designed to replace standard white lamps is LED chips. White light is often obtained by mixing radiation from a combination of LED chips with different colors of radiation, for example, blue, green and red, or blue and orange, etc.

However, in recent years, LED-based white light sources with photoluminophores converters that emit yellow or orange (red) radiation when absorbing blue or UV radiation from an LED chip have come to the fore in terms of scale of use.

A common serious drawback of existing LED white light sources is the harmful effect on the human body of intense blue radiation with a wavelength of 450-470 nm, which directly enters the human eye from LED lamps due to the principle of their operation, in which blue LEDs of relatively high intensity are precisely in the wavelength range of 450-470 nm directly forms the spectrum of the white radiation of the LED lamp, mixing, for example, with the yellow radiation of a photoluminophore excited by LEDs. Incandescent lamps are a standard in the sense of ensuring the natural color reproduction of illuminated objects, since they have a color rendering index (CRI) close to 100, which is an objective measure of the ability of the light generated by the source to accurately transmit a wide range of colors.

Due to the rapid spread of LED light sources, interest in the biomedical aspects of their application has intensified, primarily the effect of the “new” light on the psychophysiological state of a person, as well as the possible long-term effects of LED lighting on health. The urgency of the problem is associated with the fact that the emission spectrum of the most massive white LEDs with a YAG:Ce based phosphor coating differs noticeably from that for other types of lamps, as well as from the sunlight spectrum by the presence of a strong band in the blue spectral region 450-470 nm (“excess blue”) and a dip in the cyan light region of 480 nm, which have a strong effect on the circadian rhythm (biorhythm) of the human body.

Human biorhythms, being the result of human evolution that took place under the direct influence of the Sun, are controlled by a hormonal system, which, in turn, is controlled by the influence of external lighting, the only source of which throughout the existence of man as a species was the Sun, which controlled the biorhythms of the human body. The flames of a bonfire or torch, and then the light of a candle or incandescent bulb, used to illuminate in the evening for many centuries of human history, did not violate the biorhythms of the human body, due to the similarity of their spectra to the solar spectrum at sunset. In the evening, the human eye is focused on the perception of red-yellow color, blue light increases eye strain and can reduce visual acuity.

Recent studies on LED lighting have revealed the mechanisms of the influence of the spectrum of direct LED lighting on the biological clock of a person and his hormonal system. This effect is due to the significant content of the blue component in the spectrum of the white LED, which increases with time due to the high operating temperature of the LED and the aging of its phosphor.

“Excessive blue” light in the evening is perceived by the hormonal system as a person's presence in daylight. Thus, the production of melatonin, a hormone that is responsible for sleep quality, is blocked—the circadian rhythms of a person go astray and there are problems with sleep and disturbances in the hormonal system, which interferes with important physiological processes and leads to weakened immune defenses and depressive disorders. decreased performance and other negative consequences for human health.

The effect of the blue component of the spectrum on the circadian rhythm is through the pigments of the eyes (melanopsin) and the human hormonal system.

According to modern concepts, the human eye has two channels of radiation perception:
visual, for which the known 3 types of cones (color daytime vision) and sticks (“gray” twilight vision) are sensors;
a relatively recently opened visual or biological channel based on melanopsin-containing ganglion cells, which determines the secretion of the hormone melatonin into the blood and, thereby, regulates the states of activity and relaxation. Incorrect lighting and, as a result, a violation of the biochemical composition of the blood, can cause not only sleep and mental disorders, but, with prolonged exposure, contribute to the development of breast cancer.

For this reason, with a person staying for a long time under artificial lighting, the spectrum of light and the ratio of its components are especially important. This suggests that the cultivated concept of building lighting devices for lighting based on the direct use of LED radiation does not guarantee safety for the human eye and his health in general. For example, an international group of researchers from the University of Haifa (Israel), the National Center for Geophysical Data (USA) and the Scientific and Technological Institute of Light Pollution (Italy) found that LED lamps are the most dangerous to health, as they reduce the production of the hormone melatonin, which regulates biological watches and having antitumor and immunostimulating effects. Yellow sodium lamps, for example, also have this effect, but are five times smaller and do not have such a strong effect on human health.

Melatonin regulates the work of the biological clock in the human body, positively affects the immune system and, as a result, partially inhibits the development of tumors. The fact that blue light suppresses the production of this hormone has been known for a long time, but for the first time it was possible to find out quantitative indicators of how various types of electric lamps affect a person. Researchers took the level of suppression of melatonin production, which is caused by high-pressure sodium lamps giving yellow light, as a unit. In comparison, LED lamps suppress the production of melatonin more than five times stronger (per unit power).

A number of studies have shown that LED light sources cause noticeable harm to human and animal health by acting on the retina. The harm is caused by short-wave blue and violet light, which in the spectrum of such lamps in some cases has an increased intensity of up to 30% compared to conventional incandescent lamps. This short-wave radiation causes three types of injuries to the retina: photomechanical (shock energy of a wave of light energy), photothermal (tissue fiber is heated during irradiation), and photochemical (blue and violet photons can cause chemical changes in the structures of the retina). Green and white light has much less phototoxicity, and when exposed to the retina with red light, no negative changes were detected.

Sunlight is fundamental to all life on earth. Each living creature, due to the structural organization of photosensitive cells, perceives that part of the spectrum of sunlight that is vital to it. This part of the spectrum is biologically adequate for physiology and can serve as the basis for a qualitative and quantitative assessment of how the radiation spectrum of artificial light sources is suitable for a given biological object, and, accordingly, for creating LED white light sources with a biologically adequate spectrum. A biologically adequate light spectrum is a set of photon fluxes that form a matrix of control signals that ensures the harmonious operation of the functional elements (cells) of the visual analyzer, the human hormonal system and biorhythms of brain functioning.

To a large extent, the biological adequacy of the artificial white light spectrum can be assessed by the effectiveness of controlling the diameter of the pupil.

The protective functions of the retina are adapted to sunlight. The human eye functions as a natural diaphragm: a large stream of light narrows the pupil, so that only a small stream of light passes to the retina. In conditions of insufficient lighting, the pupil, on the contrary, expands.

Shortwave blue light can easily pass through the cornea, causing inflammation of the eye. The main mechanism for protecting the retina from emitting blue light is a yellow spot (macula) in the center of the retina. Through the dilated pupil, the entire excess stream of blue light directly rushes to the retina and falls on the edge of the macula, which serves as a protection for the central part of the macula, that is, where its density is low. The lower the density of the macula, the higher the likelihood of oxidative stress of retinal cells. Adequate pupil control in sunlight reduces the diameter of the pupil, thereby providing natural protection to the retina.

The dip in the spectrum of traditional LED white light sources at 480 nm, which is absent in the solar spectrum neither in the daytime, nor at sunset, falls on the region of maximum sensitivity of melanopsin, which determines the opening of the pupil of the eye, and thereby leads to inadequate control of the opening of the pupil in conditions conventional LED lighting, leading to an increase in pupil area and the total excess dose of blue light, increasing the risk of developing eye diseases.

The situation is especially complicated in children, because the lens of the child's eye is very transparent and transmits 70% more light than in an adult. Under such conditions, the total excess dose of blue light injures the retina, increasing the risk of developing eye diseases. The severity of the problem was especially noted in the decision of the last third World Congress of Pediatric Ophthalmologists, in which it was highlighted that the general tendency for safe illumination by semiconductor light sources and video-safe radiation of displays is as follows: it is necessary to have a biologically adequate spectrum that will ensure the harmonious operation of the visual analyzer and the human hormonal system.

Therefore, the creation of LED light sources with a biologically adequate spectrum of white light, solved in the present invention, is becoming increasingly relevant, especially for LED light sources intended for use in the evening, since the latest modern LED devices are SunLike (Seoul Semiconductors and Toshiba Chemicals) or Eye-Pleasing (LG Innotek), which can be used during the daytime in conditions of insufficient sunlight as additional lighting, is unsuitable for evening home lighting due to the suppression of the generation of melatonin by the high blue component of their spectrum, despite minimizing the dip in the spectrum at 480 nm. In addition, the use of such devices in the daytime should be done with caution, since today it is already known about the cataractogenic effect on the lens proteins and the rate of development of the cataract of the short-wave radiation underlying them. In India, the visual environment with a constant bright sun causes a significant increase in the number of patients with cataracts.

U.S. Pat. No. 8,513,873 B2, Aug. 20, 2013, proposes a known light emitting device including a plurality of electrically active semiconductor emitters (eg, LEDs) having different spectral output powers; and/or phosphor material, including one or more phosphors, designed to receive spectral output from at least one of the emitters of the solid body and for the response radiation of the output signal of the phosphor to provide spectral output. In one arrangement, several LEDs and several phosphors have different peak wavelengths and provide an aggregate luminous flux with less than four light emission peaks.

The light emitting device includes a reflective cup or similar support structure on which a first color LED chip and a second color LED chip are mounted. In a particular device of such a multi-chip array, the first LED chip is a blue LED chip and the second LED chip is a green LED chip. The multi-chip matrix is coated with a phosphor material, which in a particular embodiment may include a mixture of two phosphors dispersed in a polymer matrix, such as polycarbonate. The phosphors in the phosphor material are selected so as to be excited by the radiation emitted from the multi-chip matrix and in response to emit the output radiation, so that the integrated output of the light-emitting device obtained from the multi-chip array and the phosphor has the desired spectral nature.

To cover the desired spectral range, two LEDs are used, dark blue (having a spectral output centered at 460 nm, extending from 440 nm to 480 nm) and green (having a spectral output centered at 527 nm, extending from 500 nm to 560 nm) LEDs function as light sources and excite a mixture of two photophosphors: CaGa₂S₄:Eu₂₊, which emits yellowish-green light and which is excited by light with a wavelength of less than 510 nm (50% absorption), and ZnGa₂S₄:Mn₂₊, which emits an orange-red light when excited light with a wavelength of less than about 480 nm (25% absorption). The chip size of each of the two LED chips and the concentration of each of the two phosphors in the phosphor mixture are adjusted to achieve a spectral response similar to natural daylight at noon.

The conversion layer may include both a single type of photoluminophore material or quantum dot material, or a mixture of photoluminophore materials and quantum dot materials. The use of a mixture of more than one such material is advisable if a wide spectral range of emitted white radiation is desirable (high color reproduction coefficient). One of the typical approaches to obtaining warm white light with a high color reproduction factor is to use the radiation of a mixture of yellow and red conversion photophosphors.

It is believed that the cascade interaction of phosphors, which is determined by the overlap between the excitation spectrum of a photophosphor with long-wavelength radiation, for example, red, and the emission spectrum of a photophosphor with short-wavelength radiation, for example, green/yellow, results in the reabsorption of energy of short-wavelength (green/yellow) photons with radiation of long-wavelength (red) photons, reduces the efficiency of the LED and the color rendering coefficient of white radiation. In a specific example, the energy of green/yellow quanta is converted into red photons and the width of the slit bottom between the spectral emission curves of the green/yellow photoluminophore and the blue LED that excites the green/yellow photoluminophore increases. This deteriorates the color reproduction rate. Therefore, it is considered that it is necessary to minimize the interaction of the “short-wave” and “long-wave” photoluminophores. With this interaction, the most pronounced in the mixture of phosphors, is associated with a relatively low efficiency of the described known device according to U.S. Pat. No. 8,513,873 B2.

Its other disadvantages are the presence in the spectrum of the peak of phototoxic blue radiation in the range of 450-470 nm and a dip in the region of cyan light of 480 nm.

U.S. Pat. No. 8,847,478 B2, Sep. 30, 2014, which is closest to the present invention and adopted as a prototype, proposes an LED light bulb with an array of LED chips and two conversion materials (phosphors) to provide white light, which includes an auxiliary mount including the first and the second mounting area of the chip matrix. The first LED chip is installed on the first matrix mounting area, and the second LED chip is installed on the second matrix mounting area. The LED lamp is configured to emit light having a spectral distribution including at least four different color peaks to provide white light. For example, the first conversion material may at least partially cover the first LED chip and may be configured to absorb at least a portion of the light of the first color and re-emit light of the third color. In addition, the second conversion material may at least partially cover the first and/or second LED chips and may be configured to absorb at least a portion of the light of the first and/or second colors and re-emit the fourth color light. Related lighting fixtures and methods are also disclosed.

The disadvantages of the LED bulbs of U.S. Pat. No. 8,847,478 B2 are also the presence of a phototoxic blue emission peak in the spectrum in the range 450-470 nm and a dip in the cyan light region of 480 nm.

The claimed invention eliminates these disadvantages and allows to achieve the claimed technical result.

### DISCLOSURE OF INVENTION

The technical problem that the present invention solves is the creation of LED lamps with a biologically adequate spectrum of white radiation, in which the harmful effects of radiation on the human body inherent in known technical solutions are significantly reduced, and designed to replace incandescent lamps and standard LED lamps, and reliability and efficiency are increased light source.

The technical result consists in reducing the harmful effects of radiation on the human body, increasing the reliability and efficiency of the light source.

To solve the problem with the achievement of the claimed technical result, an LED light source with a biologically adequate spectrum of white radiation includes at least two white LEDs located on a heat-conducting printed circuit board with electrical leads for connecting the LEDs to a power source, and a translucent cover located above the printed circuit board, each white LED contains in the light-reflecting housing at least one chip with cean radiation, embedded in a polymer composition with its own photophosphor or a mixture of photophosphors, while at least one cyan LED coated with a composite is additionally placed on the heat-conducting printed circuit board photoluminescent film containing photoluminophore in a transparent base.

The thickness of the composite photoluminescent film is 50-200 μm, with a photoluminophore content in the range from 1:1 to 2:1 weight fractions relative to the transparent base.

The composite photoluminescent film contains a photoluminophore with the composition described by the stoichiometric formula Y_{3-y-z}Lu_{y}Ce_{z}Al₅₋ₓGaₓO₁₂, where 1.8<x<2.1, O≤y≤2.86, 0.12≤z≤0.15.

The surface of the photoluminescent film is additionally coated with a transparent protective layer.

At least one white LED is additionally coated with a composite photoluminescent film containing a photoluminophore in a transparent base.

### BRIEF DESCRIPTION OF THE DRAWINGS

FIG. 1. A schematic sectional view of an LED light source;

FIG. 2. Schematic image of the LED in an enlarged view in section;

FIG. 3. The device circuit board of the LED light source;

FIG. 4. The spectrum of the LED white light source shown in FIG. 3;

FIG. 5. The device circuit board LED light source;

FIG. 6. The spectrum of the lamp with the LED source shown in FIG. 5;

FIG. 7. Spectrum of photoluminophore;

FIG. 8. LEDlampdevice;

FIG. 9. The construction of the linear LED lamp;

FIG. 10. The spectrum of a linear LED lamp based on an LED light source with a biologically adequate spectrum of white radiation;

FIG. 11. The spectrum of a linear LED lamp based on an LED light source with a biologically adequate spectrum of white radiation.

### THE IMPLEMENTATION OF THE INVENTION

The basis of the present invention is the technical task of creating a LED white light source (illuminator) with a small form factor that uses the conversion of cyan and blue nitride light emitting diodes (LEDs) using composite photoluminescent materials based on garnet photoluminophores, with a maximum illuminator emission intensity in the range of 445-475 nm does not exceed the minimum intensity in the range 479-483 nm with a color rendering coefficient of the illuminator radiation of at least 90, high efficiency and a color temperature of 2500-3500K.

The claimed LED light source (illuminator) with a biologically adequate spectrum of white radiation includes a group of (at least two) typical, for example, flat white LEDs, each of which contains at least one gallium nitride chip emitting blue radiation, and at least one cyan LED with at least one nitride chip emitting cyan radiation, placed on a heat-conducting printed circuit board with electrical terminals for connecting the LEDs to a power source, and a translucent light-diffusing cover located above the printed circuit board and intended for output mixing and scattering of LED radiation, and on the output surfaces of the LEDs (all or cyan only), composite photoluminescent films containing in the transparent basis photoluminophore material that converts the radiation of the chips into green-cyan radiation, the spectral maximum of which is located, are absent in the known analogues wives in the range of 510-530 nm, and the half-width of the spectral line is at least 105 nm. As a material used in the photoluminescent film of the claimed invention that meets these requirements, a new phosphor is proposed, the composition of which is described by the stoichiometric formula Y_{3-y-z}Lu_{y}Ce_{z}Al₅₋ₓGaₓO₁₂, where 1.8<x<2.1, 0≤y≤2.86, 0.12≤z≤0.15.

The thickness of the photoluminescent films can be 50-200 microns, with a photoluminophore content in the range from 1:1 to 2:1 weight fractions with respect to the transparent base.

The emission spectra of LED chips are in the spectral region of excitation of the proposed photoluminophore, and the maximum emission spectrum of cyan LED chips falls into the region within the spectral range with a boundary located on the short-wavelength edge of the photoluminophore emission at a distance equal to the half-width of the photoluminophore emission spectrum from the position of its emission spectrum maximum. This allows for certain thicknesses of photoluminescent films and concentrations of photoluminophores in them to ensure that the conditions of biological adequacy of the spectrum of emitted white light are satisfied (the maximum radiation intensity of the illuminator in the range 445-475 nm does not exceed the minimum intensity in the range 479-483 nm) with high efficiency of the illuminator. The location of the maximum absorption spectrum of the conversion layer in the range 450-470 nm ensures the suppression of the harmful blue component in the range 450-470 nm in the radiation of the white LEDs of the illuminator, while slightly reducing the color reproduction coefficient of white light due to the presence of the blue-cyan component in the wavelength range about 480 nm, weakly expressed, for example, in the radiation of the most commonly used typical white LEDs, in which LED chips with emission wavelengths from the 450-470 nm range are coated with yellow (yellow-orange) YAG:Cephotophosphor.

The claimed invention is illustrated in detail FIGS. 1-11.

FIG. 1, schematically shows a cross section of the claimed LED light source with a biologically adequate spectrum of white radiation, including a substrate-printed circuit board 1, on which are placed flat white LEDs 2 and a flat cyan LED 3 with a photoluminescent film 4, and an optically translucent matte a cover 5 for outputting light, covering the internal volume 6. Conductors connecting the LEDs and electrical leads are not shown.

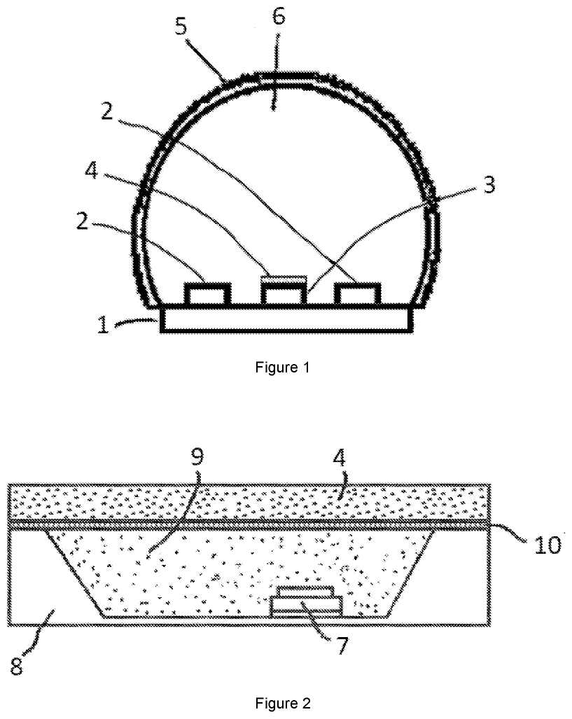

FIG. 2 schematically shows an LED (white/cyan) in an enlarged sectional view: 7—LED chip, 8—reflective cup—body of the source LED, 9—intrinsic conversion material (photoluminophore or optically transparent fill) of the source LED, 4—layer conversion material (photoluminescent film) for converting the emission spectrum of the LED, 10—a layer of optically transparent glue. Conductors connecting nitride chips with 1 substrate-printed circuit board shown in FIG. 1, not shown.

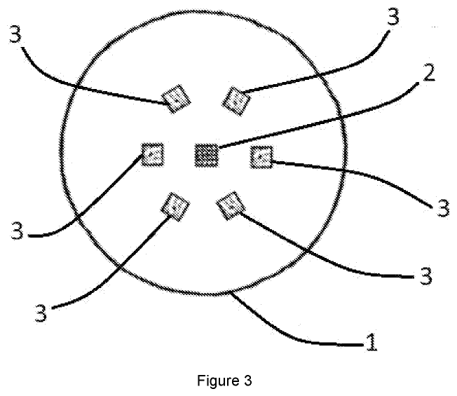

FIG. 3 schematically shows the arrangement of the printed circuit board of an LED light source with a biologically adequate spectrum of white radiation in the embodiment with one white LED and six cyan LEDs coated with a photoluminescent film: 1—heat-conducting substrate—printed circuit board, 2—white LEDs with a luminescent film of 50 μm, 3—cyan LED with a luminescent film of 130 microns. Conductors connecting the LEDs to each other and to the driver are not shown.

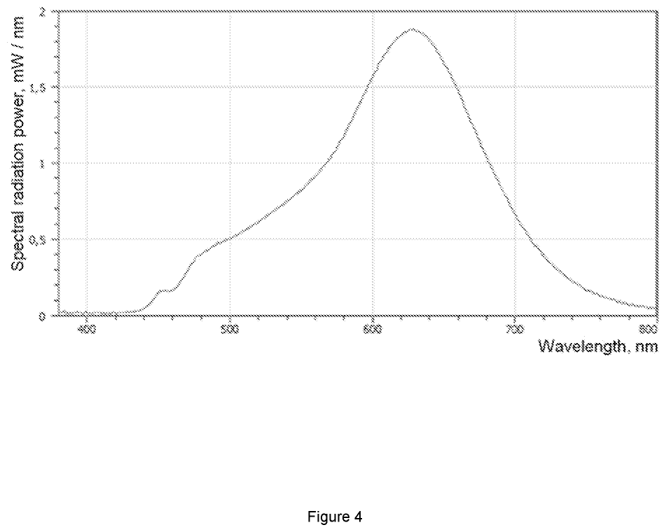

FIG. 4 shows the spectrum of the LED white light source shown in FIG. 3.

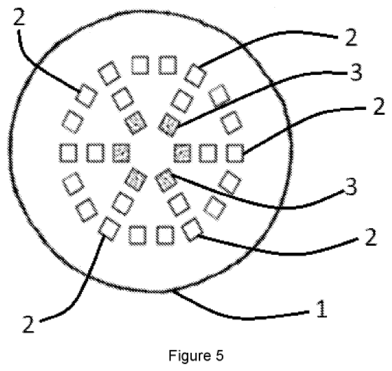

FIG. 5 schematically shows the arrangement of the printed circuit board of an LED light source with a biologically adequate spectrum of white radiation in the embodiment with twenty-four white LEDs and six cyan LEDs coated with a photoluminescent film: 1—heat-conducting substrate—printed circuit board, 2—white LEDs with a luminescent film 50 microns, 3—cyan LED with a luminescent film of 130 microns. Conductors connecting the LEDs to each other and to the driver are not shown.

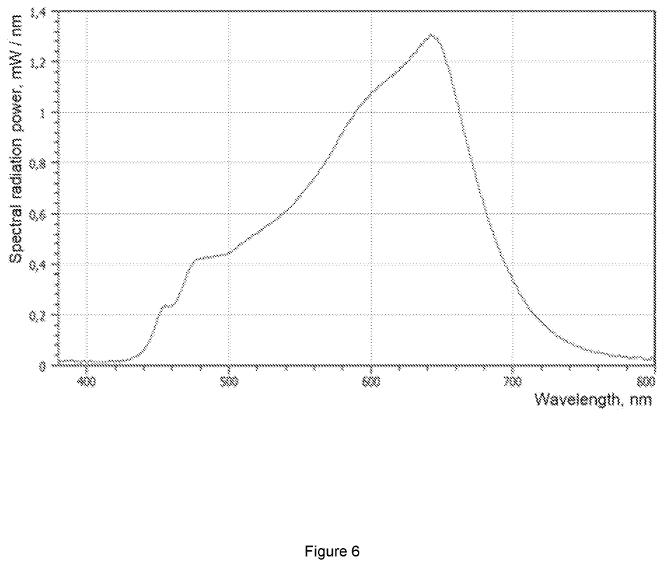

FIG. 6 shows the spectrum of the lamp with the LED white light source shown in FIG. 5.

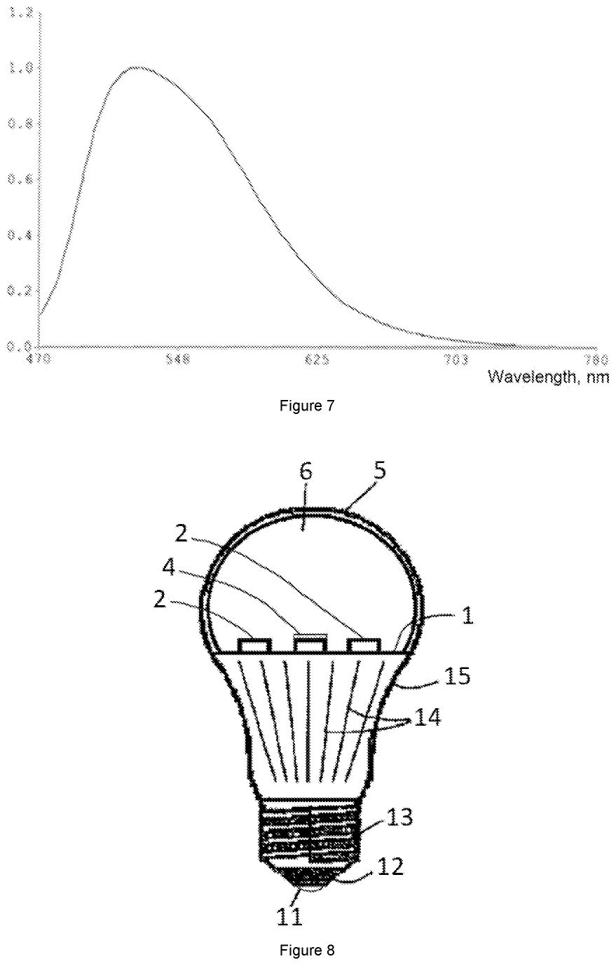

FIG. 7 shows the spectrum of the photoluminophore Y_{2.79}Ce_{0.12}Lu_{0.09}Al_{3.1}Ga_{1.9}O₁₂.

FIG. 8 schematically shows the arrangement of an LED lamp based on one embodiment of an LED light source with a biologically adequate spectrum of white radiation, including an external component covering the internal volume 6. An insulator 12 is located next to the base terminal electrical contact 11 and an electrical contact base 13. Between the optically translucent matte cover for outputting light 5 and the base 13, a housing 15 is located that includes a plurality of cooling fins 14. In one embodiment, the housing 15 is made of a material having high thermal conductivity (e.g., aluminum) with many ribs 14 formed in it. Optical translucent matte cover for light output 5 may be made of a material having a high transmittance, have different thicknesses, surface quality or patterns, and/or contain different materials to impart different optical properties to the rays emitted in different directions from the lamp, for example, above or lower than the heat-conducting substrate-printed circuit board on which the flat white LEDs 2 and the flat cyan LED 3 with the photoluminescent film 4 are placed. Conductors connecting the contacts to the driver and the substrate-printed circuit board are not shown.

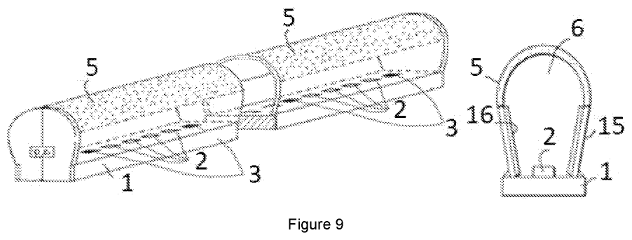

FIG. 9 schematically shows the arrangement of a linear LED lamp based on one of the embodiments of the invention of an LED light source with a biologically adequate spectrum of white radiation, including an external component covering the internal volume 6. Between an optically translucent matte cover for light output 5 and a heat-conducting substrate-printed circuit board 1 is located housing 15. In one embodiment, the housing 15 may be made of a material having high thermal conductivity (for example, aluminum) with many ribs formed in it. Optical translucent matte cover for light output 5 can be made of a material having a high transmittance, have different thicknesses, surface quality or patterns and/or contain different materials to give different optical properties to the rays emitted in different directions from the lamp, for example, above or lower than the heat-conducting substrate-printed circuit board 1, on which are placed flat white LEDs 2 and flat cyan LEDs 3 with a photoluminescent film, reflector-diffuser 16, made, for example, from WhiteOptics® F16-98 film from White Optics, LLC (USA). The conductors connecting the contacts to the substrate-printed circuit board are not shown.

A typical white LED includes at least one gallium nitride chip with blue radiation in the 445-465 nm range, housed in a reflective cup (in a light-reflecting LED casing), embedded in a polymer composition with its own photophosphor or a mixture of photophosphors that convert radiation chip into yellow or yellow-red radiation, which gives a mixture of chip radiation with warm-white radiation with a correlated color temperature of 2500-3500K and a color rendering coefficient of more than 90.

The cyan LED includes at least one chip with cyan radiation in the range 475-490 nm, placed in a reflective cup (in the light-reflecting LED casing), filled with optically transparent material.

In the claimed solution, in contrast to the known ones, the light source further includes at least one LED with cyan radiation in the range 475-490 nm, coated with a composite photoluminescent film containing in a transparent base a photoluminophore that converts the specified cyan radiation into green radiation with a spectral line whose peak is in the range of 510-530 nm, and the line half-width is not less than 105 nm, and in the total white radiation of the indicated LED white light source, the maximum radiation intensity in the spectral range of 459-464 nm does not exceed the minimum radiation intensity in the spectral range 479-483 nm. At a certain thickness of the composite photoluminescent film and the concentration of the photoluminophore in it, the conditions for the biological adequacy of the spectrum of the emitted white light are ensured. The above composite photoluminescent film may be coated with white LEDs.

The LED white light source with a biologically adequate emission spectrum works as follows. The radiation of the cyan LED nitride chip 7, including that reflected from the reflecting cup—the housing 8 of the initial cyan LED, passes through the optically transparent fill 9 of the LED and falls on the surface of the layer of conversion material 4 (photoluminescent film), which serves to convert the emission spectrum of the cyan LED to green-cyan radiation, then goes into the internal volume, where it is mixed with white radiation of flat white LEDs 2, which can also be coated with layers of conversion material 4, and then goes out through a translucent matte cover for light output, which additionally scatters and homogenizes the radiation of the light source In this case, the necessary spectral distribution of white color is created, which is determined to a large extent by the properties of the materials of the conversion layers, primarily the composition, dispersion of the photophosphors and the thickness of the conversion layers. The claimed solution allows to eliminate or significantly reduce the harmful effects of intense blue radiation on the human body.

Photoluminescent films are made in the form of dispersion in an optically transparent material for LED emissions and photoluminophore.

Transparent materials may include polymeric and inorganic materials. Polymeric materials include (but are not limited to): acrylates, polycarbonate, fluoroacrylates, perfluoroacrylates, fluorophosphonate polymers, fluorosilicones, fluoropolyimides, polytetrafluoroethylene, fluorosilicones, sol gels, epoxies, thermoplastics and thermos, and plastics. Fluorine-containing polymers are particularly useful in the ultraviolet wavelength ranges of less than 400 nm, and infrared wavelengths of more than 700 nm, due to their low light absorption in these wavelength ranges. Typical inorganic materials include, but are not limited to: silicon dioxide, optical glasses, and chalcogenide glasses.

In some cases, it is preferable to introduce a photoluminophore into the material of a photoluminescent film, for example, a transparent plastic such as polycarbonate, PET, polypropylene, polyethylene, acrylic, formed by extrusion. In this case, the photoluminescent film can be prefabricated in sheets. In this case, a suspension of photoluminophore, surface-active substances (surfactants) and polymer is prepared in an organic solvent. The suspension can then be formed into a sheet by extrusion or injection molding, or poured onto a flat substrate, for example, glass, followed by drying. The resulting sheet can be separated from the temporary substrate, cut and attached to the LED using a solvent or cyanoacrylate adhesive. In a specific case, from a suspension of particles of an experimental photoluminophore based on yttrium-gadolinium-cerium (Y, Gd, Ce)₃Al₅O₁₂aluminogranate in a solution of polycarbonate in methylene chloride, sheets of different thicknesses were extruded. The film should have a sufficiently large thickness to ensure the achievement of the necessary spectral values of mixed white light. The effective thickness is determined by the processes of optical scattering in the photophosphors used and lies, for example, between 50 and 200 microns.

The photoluminescent films used in the examples of the present invention are made on the basis of a two-component silicone compound OE 6636 manufactured by Dow Corning (OE) with the addition of specially designed photoluminophores (LF) with the general stoichiometric formula: Y_{3-y-z}Lu_{y}Ce_{z}Al₅₋ₓGaₓO₁₂ where 1.8<x<2.1, 0≤y≤2.86, 0.12≤z≤0.15.

In particular:
LF-5870 [Lu_{2.85}Ce_{0.15}Al₄Ga₁O₁₂] with λp=510.8 nm;
LF-4940 [Y_{2.79}Ce_{0.12}Lu_{0.09}Al_{3.1}Ga₁₂] with λp=528 nm;
LF-5115 [Y_{2.88}Ce_{0.12}Al₃Ga₂O₁₂] with λp=525 nm;
LF-5260 [Y_{2.88}Ce_{0.12}Al_{2.9}Ga_{2.1}O₁₂] with λp=525 nm.

Table 1 presents data on the weight ratios of the silicone base (OE) and phosphors (LF), as well as the thicknesses of the films used:

TABLE 1

| | | Ratio | Film thickness, |
|---|---|---|---|
| N^{o} | LF | OE:LF | microns |
| 1 | LF-5870 | 1:1, 5 | 50-180 |
| 2 | - ″ - | 1:1, 8 | 120-140 |
| 3 | LF-4940 | 1:1 | 50-60 |
| 4 | - ″ - | 1:1, 5 | 170-200 |
| 5 | - ″ - | 1:1, 3 | 130 |
| 6 | - ″ - | 1:1, 8 | 120-130 |
| 7 | - ″ - | 1:2 | 130-140 |
| 8 | LF-5115 | 1:1, 8 | 120-140 |
| 9 | LF-5260 | 1:1, 8 | 120-130 |

Photoluminescent films were made by thoroughly mixing the corresponding photoluminophoreweigheds in a pre-prepared mixture of two initial components of the OE 6636 silicone optical compound, followed by applying a photoluminescent mixture of the desired thickness to the dacron film using an applicator and subsequent annealing in air for 1 hour at a temperature of 100° C. After annealing, the photoluminescent film is easily separated from the lavsan film and, after cutting, is glued to SMD LEDs with an OE 6636 silicone optical compound.

Photoluminophore can be conformally applied as a coating on the surface of the LED (FIG. 2), for example, by spraying, spreading paste, sedimentation or electrophoresis from a suspension of photoluminophore in a liquid. One of the problems associated with coating an LED with a phosphor is applying a uniform reproducible coating to the LED. When spraying, applying paste and sedimentation methods, liquid suspensions are used to apply photoluminophore particles to an LED. The uniformity of the coating is highly dependent on the viscosity of the suspension, the concentration of particles in the suspension, and environmental factors such as, for example, ambient temperature and humidity. Coating defects due to flows in the suspension before drying and daily changes in coating thickness are common problems.

The surface of the photoluminescent film can be further coated with a transparent protective layer, which prevents moisture and/or oxygen from entering the film, increasing the reliability of the light source, since some types of photoluminophores, for example, sulfide ones, are subject to damage from moisture. The protective layer can be made of any transparent material that traps moisture and oxygen, for example, inorganic materials such as silicon dioxide, silicon nitride or aluminum oxide, as well as organic polymeric materials or a combination of polymeric and inorganic layers. Preferred materials for the protective layer are silicon dioxide and silicon nitride.

The protective layer can also perform the function of optical enlightenment of the grain boundary of the photophosphor with the atmosphere and reduce the reflection of the primary radiation of the LED and the secondary radiation of the photophosphor at this boundary, reducing the absorption loss of the radiation of the photophosphor in its grains, and thereby increasing the efficiency of the light source.

The protective layer can also be applied by finishing surface treatment of photoluminophore grains, in which, for example, a nanosized film of zinc silicate 50-100 nm thick is formed on the grain surface, which illuminates the grain boundary of the photoluminophore. The composition and thickness of the films are selected empirically to obtain a biologically adequate spectrum of the luminaire for the specific types of serial LEDs used.

### EXAMPLE 1

An LED source with a biologically adequate white emission spectrum for self-contained luminaires was manufactured using Lumileds SMD LEDs: 6 white type GTM30302 and one L135-B475003500001 cyan LED with a 50 μm thick photoluminescent film. The photoluminescent films are based on the OE 6636 optical silicone compound manufactured by Dow Corning with the addition of the Lu_{2.85}Ce_{0.15}Al₄Ga₁O₁₂photoluminophore in a ratio of 1:1.5. The films are glued with the same two-component compound OE 6636, which has high transparency in the visible range of the spectrum. The steady luminous flux of 200 lm when powered by three AA batteries connected in series, with a CRI of 92.6% and a T_{c} of 2354K.

### EXAMPLE 2

An LED source with a biologically adequate spectrum of white radiation for stand-alone luminaires, the LED configuration of which is shown in FIG. 3, and the spectrum in FIG. 4, is made using Lumileds SMD LEDs: 6 white type GTM30302, coated with a 100 μm thick photoluminescent film, and one cyan LED of type L135-B475003500001 with an adhesive photoluminescent film 150 μm thick. The photoluminescent films are based on the OE 6636 optical silicone compound manufactured by Dow Corning with the addition of the Lu_{2.85}Ce_{0.15}Al₄Ga₁O₁₂photoluminophore in a ratio of 1:1.5. The films are glued with the same two-component compound OE 6636, which has high transparency in the visible range of the spectrum. The spectrum of photoluminophore used is shown in FIG. 7 (λp=528 nm). The steady luminous flux of 105 lm when powered by three AA batteries connected in series, with a CRI of 92.6% and a T_{c} of 2354K.

### EXAMPLE 3

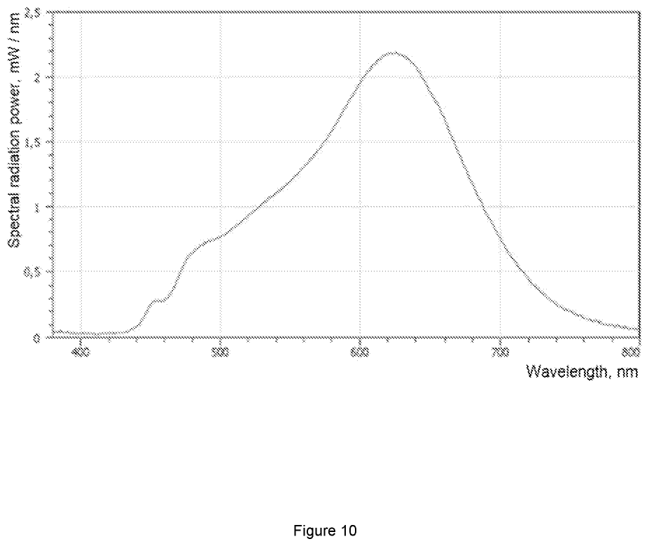

An LED retrofit lamp with a biologically adequate spectrum of white radiation, the spectrum of which is shown in FIG. 10, was made using Lumileds SMD LEDs: 12 white L130-3090003000W21 type and three cyan L135-B475003500001 type LEDs. The output surfaces of the cyan LEDs are coated with a 130 μm thick photoluminescent film based on the OE 6636 optical two-component silicone compound manufactured by Dow Corning with the addition of Y_{2.79}Ce_{0.12}Lu_{0.09}Al_{3.1}Ga_{1.9}O₁₂ photoluminescent in a 1:1 ratio. The films are glued with OE 6636 compound. The steady luminous flux of a lamp is 800 lm at a power consumption of 8.5 W, power factor 0.45, light output 94.12 lm/W, CRI 93%, T_{c} 3000K.

### EXAMPLE 4

An LED retrophitic lamp based on an LED light source with a biologically adequate spectrum of white radiation—the equivalent of a 100 W incandescent lamp, the spectrum of which is shown in FIG. 10, manufactured using Lumileds SMD LEDs: six cyan L135-B475003500001 type LEDs with a 120-130 micron thick photoluminescent film and 24 white GTM30302 type LEDs. The photoluminescent film was created on the basis of an optical silicone compound OE 6636 manufactured by DowCorning with the addition of a Y_{2.79}Ce_{0.12}Lu_{0.09}Al_{3.1}Ga_{1.9}O₁₂photoluminophore in a ratio of 1:1.8. The films are glued with a two-component compound OE 6636. The spectrum of the used photoluminophore is shown in FIG. 7.

The steady luminous flux of the lamp is 1580 lm at a power consumption of 16.4 W, power factor 0.46, light output 96 lm/W, CRI 92% and T_{c} 3000K.

### EXAMPLE 5

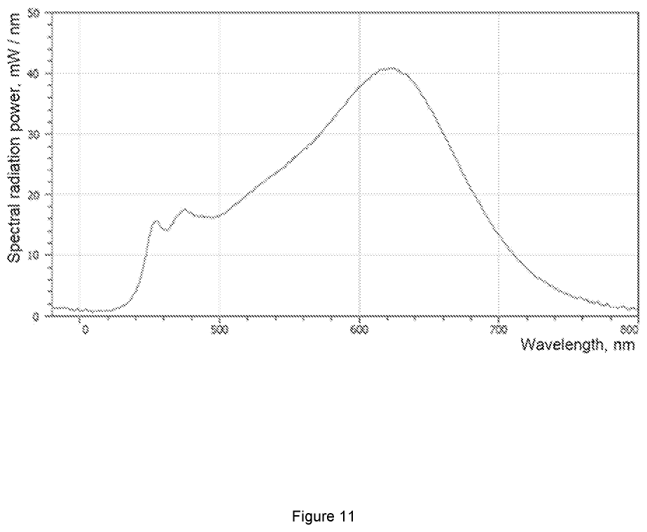

A 560 mm linear LED lamp, the spectrum of which is shown in FIG. 11, manufactured using Lumileds SMD LEDs: 48 white L130-3090003000W21 type and 12 cyan L135-B475003500001 type LEDs. The output surfaces of the cyan LEDs are coated with a 200 μm thick photoluminescent film based on the Dow Corning optical two-component silicone compound OE 6636 with the addition of Y_{2.79}Ce_{0.12}Lu_{0.09}Al_{3.1}Ga_{1.9}O₁₂photoluminophore in a 1:1 ratio. The films are glued with OE 6636 compound. The steady luminous flux of the lamp is 3 110 lm at a power consumption of 30.7 W (constant voltage 51.13 V), light output 101 lm/W, CRI 92%, T_{c} 2900K.

1. An LED white light source with a biologically adequate emission spectrum, including at least two white LEDs located on a heat-conducting printed circuit board with electrical leads for connecting the LEDs to a power source, and a translucent cover located above the printed circuit board, each white LED containing a light-reflecting case, at least one chip with cyan radiation, embedded in a polymer composition with its own photophosphor or a mixture of photophosphors, characterized in that at least one LED with cyan radiation, coated with a composite photoluminescent film, is additionally placed on the heat-conducting printed circuit board, containing in a transparent base photoluminophore.

2. The LED white light source according to claim 1, characterized in that the thickness of the composite photoluminescent film is 50-200 μm, with a photoluminophore content in the range from 1:1 to 2:1 weight fractions with respect to the transparent base.

3. The LED white light source according to claim 1, characterized in that the composite photoluminescent film contains a photoluminophore with the composition described by the stoichiometric formula Y_{3-y-z}Lu_{y}Ce_{z}Al₅₋ₓGaₓO₁₂, where 1.8<x<2.1, 0≤y≤2 86, 0.12≤z≤0.15.

4. The LED white light source according to claim 1, characterized in that the surface of the photoluminescent film is additionally coated with a transparent protective layer.

5. The LED white light source according to claim 1, characterized in that at least one white LED is additionally coated with a composite photoluminescent film containing a photoluminophore in a transparent base.
